(19) United States
(12) Patent Application Publication
(10) Pub. No.: US 2024/0096977 A1
(43) Pub. Date: Mar. 21, 2024

(54) TFT SUBSTRATE AND MANUFACTURING METHOD THEREOF, LIQUID CRYSTAL DISPLAY PANEL AND OLED DISPLAY PANEL

(71) Applicant: TCL CHINA STAR OPTOELECTRONICS TECHNOLOGY CO., LTD., Shenzhen (CN)

(72) Inventors: Kaining LI, Shenzhen (CN); Chunliu YANG, Shenzhen (CN)

(21) Appl. No.: 17/767,978

(22) PCT Filed: Apr. 1, 2022
(86) PCT No.: PCT/CN2022/084736

§ 371 Date: Apr. 11, 2022

(30) Foreign Application Priority Data
Mar. 16, 2022 (CN) 202210256859.3

(51) Int. Cl. H01L 29/417; G02F 1/1368; H01L 29/49; H01L 29/66; H10K 59/124

(52) U.S. Cl. CPC H01L 29/41733; G02F 1/1368; H01L 29/495; H01L 29/6675; H10K 59/124

(57) ABSTRACT

A TFT substrate and a manufacturing method thereof, a liquid crystal display panel and an OLED display panel are provided. The TFT substrate provided by the embodiment of the present application is obtained by setting the source electrode and the drain electrode to be etched from a conductive layer, the conductive layer includes a first metal layer and a second metal layer that are stacked and arranged, and the standard electrode potential of the first metal layer is set to be lower than the standard electrode potential of the second metal layer, the thickness of the first metal layer is set to 50Å˜150Å, which is beneficial to make the etched source and drain electrodes have smaller taper angles.

### FIELD OF INVENTION

The present application relates to a field of display, and particularly to a TFT substrate and a manufacturing method thereof, a liquid crystal display panel and an OLED display panel.

### BACKGROUND

Thin film transistors (TFTs) are an important part of display devices. TFTs can be formed on glass substrates or plastic substrates. They are usually used as switching components and driving components in the display devices such as liquid crystal display (LCD) devices, organic light emitting diode display (OLED) devices, and so on.

Compared with a-si (amorphous silicon), oxide semiconductor TFTs have following unique advantages. A sub-bandgap state density of oxide semiconductors is much smaller than that of amorphous silicon, making a subthreshold swing of oxide semiconductor TFTs small. Compared with amorphous silicon, metal oxide semiconductors are more prone to band conduction and have higher mobility. Compared with low-temperature polysilicon thin film transistors, oxide semiconductor TFTs show better uniformity. Due to more difficult to generate and transport holes, oxide semiconductor TFTs show extremely low leakage current, and the lower leakage current can realize low refreshing driving requirements of TFT.

However, source and drain electrodes of oxide semiconductor TFTs usually need to be etched to form a predetermined pattern. After etching, sides of the obtained source and drain electrodes are usually perpendicular to a substrate, that is, a taper angle is about 90 degrees. However, when the taper angle is about 90 degrees, it is difficult for a passivation layer deposited over the source and drain electrodes to adhere to the surface of the sides of the source and drain electrodes, resulting in the passivation layer being easily removed from the source and drain electrodes and falls off, and the source and drain electrodes cannot be effectively protected.

### SUMMARY OF DISCLOSURE

Embodiments of the present application provide a TFT substrate and a manufacturing method thereof, a liquid crystal display panel and an OLED display panel. In the TFT substrate, taper angles of the source and drain electrodes are small, and the passivation layer can be better attached to the source and drain electrodes, and it is not easy to fall off from the source and drain electrodes, so the source and drain electrodes can be effectively protected.

In a first aspect, embodiments of the present application provides a TFT substrate, comprising a substrate, a gate electrode, an active layer, a source and drain layer, and a passivation layer, wherein the gate electrode and the active layer are both arranged between the substrate and the source and drain layer, the passivation layer covers a side of the source and drain layer away from the substrate, and the source and drain layer comprises a source electrode and a drain electrode arranged at intervals; and
the source electrode and the drain electrode are both obtained from etching a conductive layer, the conductive layer comprises a first metal layer and a second metal layer that are arranged in a stack, the first metal layer is arranged on a side of the second metal layer away from the substrate, a standard electrode potential of the first metal layer is lower than a standard electrode potential of the second metal layer, and a thickness of the first metal layer is 50 Å to 150 Å.

In some embodiments, a material of the first metal layer is a molybdenum-titanium alloy, molybdenum or a molybdenum-niobium alloy, a material of the second metal layer is copper, and a thickness the second metal layer is 2000Å to 8000 Å.

In some embodiments, the conductive layer further comprises a third metal layer, and the third metal layer is disposed on a side of the second metal layer away from the first metal layer; and

a material of the third metal layer is a molybdenum-titanium alloy, molybdenum or a molybdenum-niobium alloy, and a thickness of the third metal layer is 100Å to 500 Å.

In some embodiments, an angle between a side of the source electrode and a plane where the substrate is located is 50° to 70°, and an angle between a side of the drain electrode and the plane where the substrate is located is 50° to 70°.

In some embodiments, the TFT substrate further comprises a gate insulating layer, the substrate, the gate electrode, the gate insulating layer, the active layer, the source and drain layer, and the passivation layer that are stacked in sequence; and
wherein the gate insulating layer covers the gate, the active layer and the gate are arranged correspondingly, the source electrode and the drain electrode are both in contact with the active layer, and the passivation layer covers the source and drain layer and the active layer.

In some embodiments, the TFT substrate further comprises a gate insulating layer and an interlayer insulating layer, the substrate, the active layer, the gate insulating layer, the gate electrode, the interlayer insulating layer, the source and drain layers, and the passivation layer that are stacked in sequence; and
wherein the gate insulating layer covers the active layer, and the interlayer insulating layer covers the a gate, the active layer and the gate are arranged correspondingly, and a source contact hole and a drain contact hole are formed in the gate insulating layer and the interlayer insulating layer, and the source electrode is in contact with the active layer through the source contact hole, the drain electrode is in contact with the active layer through the drain contact hole, and the passivation layer covers the source and drain layer.

In a second aspect, embodiments of the present application further provides a manufacturing method of a TFT substrate, comprising:
providing a substrate, and arranging a gate electrode, an active layer and a conductive layer on the substrate, wherein:
the gate electrode and the active layer are both arranged between the substrate and the source and drain layer, the passivation layer covers a side of the source and drain layer away from the substrate; and
the conductive layer comprises a first metal layer and a second metal layer that are arranged in a stack, the first metal layer is arranged on a side of the second metal layer away from the substrate, a standard electrode potential of the first metal layer is lower than a standard electrode potential of the second metal layer, and a thickness of the first metal layer is 50Å to 150 Å;
etching the conductive layer, and obtaining the source and drain layer, wherein the source and drain layer comprises a source electrode and a drain electrode arranged at intervals; and
arranging a passivation layer on a side of the source and drain layer away from the substrate.

In some embodiments, a material of the first metal layer is a molybdenum-titanium alloy, molybdenum or a molybdenum-niobium alloy, a material of the second metal layer is copper, and a thickness the second metal layer is 2000Å to 8000 Å.

In some embodiments, the conductive layer further comprises a third metal layer, and the third metal layer is disposed on a side of the second metal layer away from the first metal layer; and
a material of the third metal layer is a molybdenum-titanium alloy, molybdenum or a molybdenum-niobium alloy, and a thickness of the third metal layer is 100Å to 500 Å.

In some embodiments, an angle between a side of the source electrode and a plane where the substrate is located is 50° to 70°, and an angle between a side of the drain electrode and the plane where the substrate is located is 50° to 70°.

In a third aspect, embodiments of the present application provide a liquid crystal display panel, comprising:
a first substrate;
a second substrate disposed opposite to the first substrate, wherein the second substrate is the above-mentioned TFT substrate; and
a liquid crystal layer sandwiched between the first substrate and the second substrate.

In some embodiments, a material of the first metal layer is a molybdenum-titanium alloy, molybdenum or a molybdenum-niobium alloy, a material of the second metal layer is copper, and a thickness the second metal layer is 2000Å to 8000 Å.

In a fourth aspect, embodiments of the present application provide an OLED display panel, comprising:
a driving substrate, wherein the driving substrate is the above-mentioned TFT substrate; and
an OLED device disposed on the driving substrate, wherein the OLED device is electrically connected to the driving substrate.

The TFT substrate provided in the embodiment of the present application is obtained by setting the source electrode and the drain electrode by etching a conductive layer, the conductive layer comprises a first metal layer and a second metal layer that are stacked and arranged, and the standard electrode potential of the first metal layer is set to be low the standard electrode potential of the second metal layer, so during the etching process of the conductive layer, a galvanic corrosion effect can be formed between the first metal layer and the second metal layer, and the first metal layer acts as an anode, and the second metal layer acts as a cathode. Compared with the technical solution of setting the thickness of the first metal layer to 300 Å in the related art, since in this embodiment of the present application, a thickness of the first metal layer is 50Å to 150 Å, so the thickness of the first metal layer is greatly reduced, thereby reducing a contact area between the first metal layer and the etching solution and increasing the b/a ratio between the contact area b of the cathode and the etching solution and the contact area a of the anode and the etching solution. It is known that when b/a increases, the corrosion rate of the anode is increased, so a larger gap will be formed between the first metal layer and the second metal layer, which is beneficial to increase the corroded area of the edge of the second metal layer facing the first metal layer, so that it is beneficial to reduce the taper angle of the source electrode and the drain electrode. When the taper angle of the source electrode and the drain electrode obtained by etching is small, the passivation layer can be better attached to the source electrode and the drain electrode and will not easily fall off from the source electrode and the drain electrode, so that the source electrode 61 and the drain electrode can be effectively protected.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a flowchart of a manufacturing method of a TFT substrate according to an embodiment of the present application.

FIG. 2 is a schematic diagram of forming a gate electrode, a gate insulating layer and an active layer on a substrate according to an embodiment of the present application.

FIG. 3 is a schematic diagram of forming a conductive layer on an active layer and a gate insulating layer according to an embodiment of the present application.

FIG. 4 is a schematic cross-sectional structural diagram of a conductive layer provided by an embodiment of the present application.

FIG. 5 is a schematic diagram of source and drain electrodes obtained by etching a conductive layer according to an embodiment of the present application.

FIG. 6 is a schematic diagram of a process of etching a conductive layer in the manufacturing method of the TFT substrate according to an embodiment of the present application.

FIG. 7 is a schematic diagram of effects after completing etching of the conductive layer in the manufacturing method of the TFT substrate of FIG. 6.

FIG. 8 is a schematic diagram of a process of etching a conductive layer in the manufacturing method of fabricating the TFT substrate according to another embodiment of the present application.

FIG. 9 is a schematic diagram of effects after completing etching of the conductive layer in the manufacturing method of the TFT substrate of FIG. 8.

FIG. 10 is a schematic diagram of a first structure of a TFT substrate provided by an embodiment of the present application.

FIG. 11 is a schematic diagram of a second structure of a TFT substrate provided by the embodiment of the present application.

FIG. 12 is a schematic structural diagram of a liquid crystal display panel according to an embodiment of the present application.

FIG. 13 is a schematic structural diagram of an OLED display panel provided by an embodiment of the present application.

### DETAILED DESCRIPTION

Technical solutions in the embodiments of the present application will be clearly and completely described below with reference to the accompanying drawings in the embodiments of the present application. Obviously, the described embodiments are only a part of the embodiments of the present application, but not all of the embodiments. Based on the embodiments in this application, all other embodiments obtained by those skilled in the art without creative efforts shall fall within the protection scope of this application.

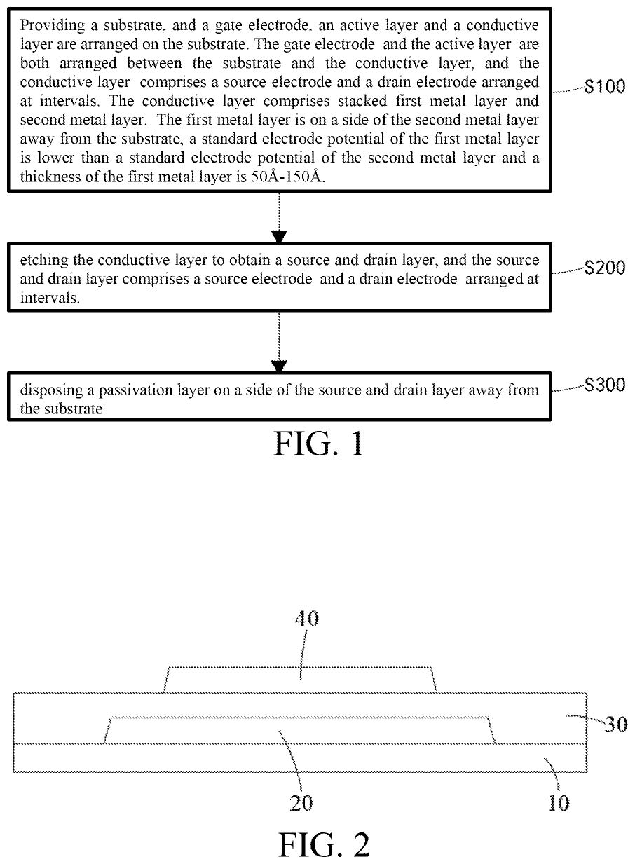

Please refer to FIG. 1, which is a flowchart of a manufacturing method of a TFT substrate provided by an embodiment of the present application. The embodiment of the present application provides a method for fabricating a TFT substrate, comprising:

Step S100: please refer to FIGS. 2-4, a substrate 10 is provided, and a gate electrode 20, an active layer 40 and a conductive layer 50 are arranged on the substrate 10. The gate electrode 20 and the active layer 40 are both arranged between the substrate 10 and the conductive layer 50, and the conductive layer 50 comprises a source electrode 61 and a drain electrode 62 arranged at intervals. The conductive layer comprises stacked first metal layer 51 and second metal layer 52. The first metal layer 51 is on a side of the second metal layer 52 away from the substrate 10, a standard electrode potential of the first metal layer 51 is lower than a standard electrode potential of the second metal layer 52, and a thickness of the first metal layer 51 is 50Å-150 Å.

It can be understood that the first metal layer 51 is the topmost metal layer in the conductive layer 50.

For example, a thickness h of the first metal layer 51 may be 50 Å, 55Å, 60 Å, 65Å, 70 Å, 75Å, 80 Å, 85Å, 90 Å, 95Å, 100 Å, 105Å, 110 Å, 115Å, 120 Å, 125Å, 130 Å, 135Å, 140 Å, 145Å, 150 Å, etc.

For example, a material of the first metal layer 51 may be molybdenum-titanium alloy (MoTi), molybdenum (Mo), or molybdenum-niobium alloy (MoNb). The standard electrode potential of molybdenum-titanium alloy (Mo:Ti in a molar ratio of 1:1) is 0.29V, the standard electrode potential of molybdenum is −0.2V, and the standard electrode potential of molybdenum-niobium alloy (Mo:Nb in a molar ratio of 9:1) is −0.1V.

For example, a material of the second metal layer 52 may be copper (Cu), and a thickness of the second metal layer 52 may be 2000 Å to 8000 Å, for example, 2000Å, 2500 Å, 3000Å, 3500 Å, 4000Å, 4500 Å, 5000Å, 5500 Å, 6000Å, 6500 Å, 7000Å, 7500 Å, 8000 Å, etc. It is known that a standard electrode potential of copper (Cu) is 0.34V, that is, the standard electrode potential of molybdenum-titanium alloy (MoTi), molybdenum (Mo) or molybdenum-niobium alloy (MoNb) is lower than the standard electrode potential of copper (Cu).

It can be understood that the second metal layer 52 is the metal layer with the largest thickness in the conductive layer 50. By setting the material of the second metal layer 52 to be copper (Cu), a conductivity of the conductive layer 50 can be improved.

It should be noted that the second metal layer 52 can be protected and the copper in the second metal layer 52 can be prevented from being oxidized by disposing the first metal layer 51 on an upper surface of the second metal layer 52.

Please refer to FIG. 4. FIG. 4 is a schematic cross-sectional structure diagram of a conductive layer provided by an embodiment of the present application. The conductive layer 50 may further comprise a third metal layer 53, and the third metal layer 53 is disposed on a side of the second metal layer 52 away from the first metal layer 51. It should be noted that, by disposing the third metal layer 53 on the lower surface of the second metal layer 52, the diffusion of copper elements in the second metal layer 52 can be blocked and the properties of the semiconductor material in the active layer 40 affected by diffusing of the copper elements into the active layer 40 can be prevented.

For example, a material of the third metal layer 53 may be a molybdenum-titanium alloy, molybdenum or a molybdenum-niobium alloy, and a thickness of the third metal layer 53 is 100Å to 500 Å, such as 100Å, 150Å, 200 Å, 250Å, 300 Å, 350Å, 400 Å, 450Å, 500 Å, etc.

For example, the first metal layer 51, the second metal layer 52, and the third metal layer 53 are all fabricated by physical vapor deposition (PVD).

For example, “disposing the gate electrode 20, the active layer 40 and the conductive layer 50 on the substrate 10” may specifically comprise:

S110: referring to FIG. 2, the gate electrode 20, the gate insulating layer 30 and the active layer 40 are sequentially formed on the substrate 10 in a stack;

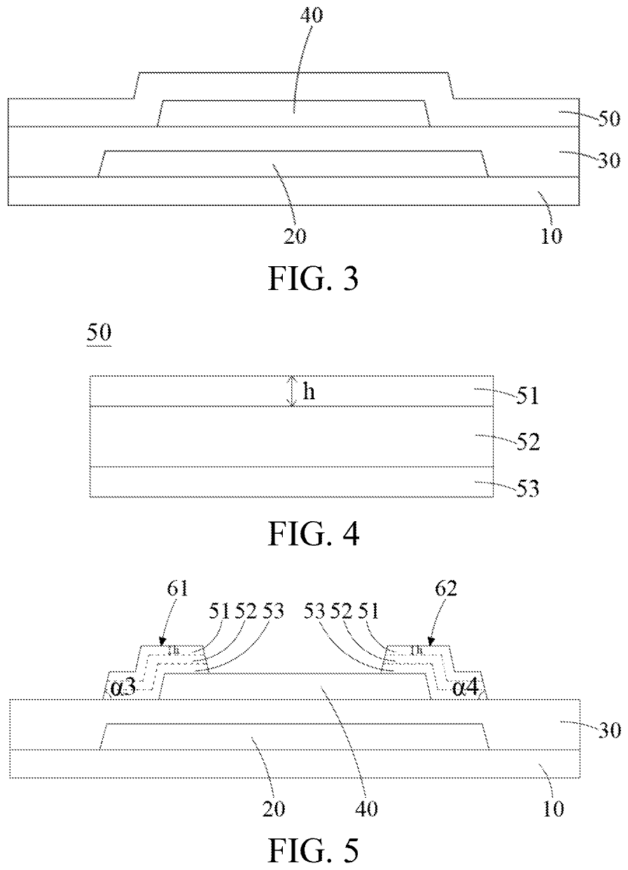

S120: referring to FIGS. 3-4, a conductive layer 50 is formed on the active layer 40 and the gate insulating layer 30.

For example, the substrate 10 may be a rigid substrate or a flexible substrate, a material of the rigid substrate may be glass, and a material of the flexible substrate may be a polymer such as polyimide.

For example, a material of the gate 20 may be metal, and in some embodiments, the material of the gate 20 may comprise one or a plurality of aluminum (Al), silver (Ag), tungsten (W), copper (Cu), nickel (Ni), chromium (Cr), molybdenum (Mo), titanium (Ti), platinum (Pt), tantalum (Ta) and neodymium (Nd). In the embodiments of the present application, “a plurality of” may refer to two or more, such as three, four, five, six, seven, eight, nine, ten, eleven, and the like.

For example, the method for fabricating the gate electrode 20 may comprise: depositing a metal layer, and patterning the metal layer to obtain the gate electrode 20. In some embodiments, the metal layer may be deposited by physical vapor deposition (PVD) such as sputtering, and the metal layer may be patterned by dry etching or wet etching.

For example, a material of the gate insulating layer 30 may comprise one or a plurality of silicon nitride (SiNx), silicon oxide (SiOx), and silicon oxynitride (SiOxNy). For example, the gate insulating layer 30 may be fabricated by chemical vapor deposition (CVD).

For example, a material of the active layer 40 may comprise oxide semiconductors, such as indium zinc oxide (IZO), gallium indium oxide (IGO), indium gallium zinc oxide (IGZO), indium gallium tin oxide (IGTO), Indium Gallium Zinc Tin Oxide (IGZTO), etc. In other embodiments, the material of the active layer 40 may also be amorphous silicon, single crystal silicon, low temperature polysilicon, or the like.

For example, the fabrication method of the active layer 40 may comprise: depositing an oxide semiconductor layer, and patterning the oxide semiconductor layer to obtain the active layer 40. In some embodiments, the oxide semiconductor layer may be deposited by chemical vapor deposition (CVD), and the oxide semiconductor layer may be patterned by dry etching or wet etching.

After the step S100, the manufacturing method of the TFT substrate according to the embodiment of the present application may further comprise:

Step S200, referring to FIG. 5, the conductive layer 50 is etched to obtain a source and drain layer, and the source and drain layer comprises a source electrode 61 and a drain electrode 62 arranged at intervals.

For example, the conductive layer 50 may be etched by a wet etching method. Compared with dry etching, an etching rate of wet etching is higher, so that the production efficiency of the TFT substrate can be improved.

Exemplarily, when the conductive layer 50 is etched by a wet etching method, the etchant used may comprise hydrogen peroxide. It can be understood that the etching solution of the hydrogen peroxide system has the advantages of constant etching rate, easy control, and simple post-processing. Preferably, the etching solution does not contain fluorine, which has little environmental pollution, and will not cause damage to the glass substrate during the etching process.

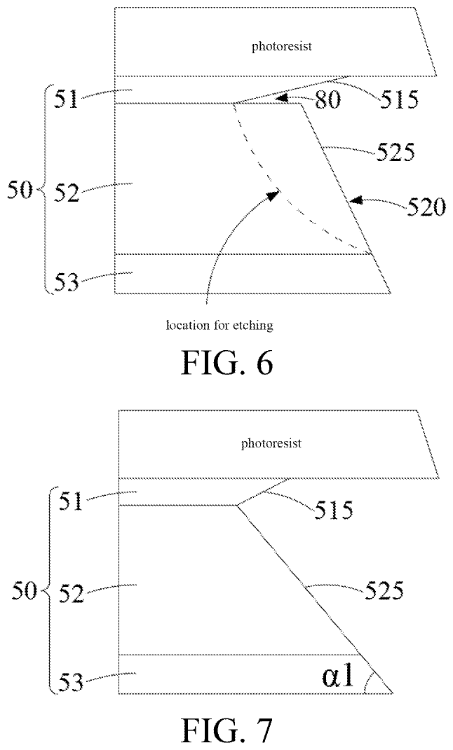

Please refer to FIG. 6 and FIG. 7. FIG. 6 is a schematic diagram of a process of etching the conductive layer in the manufacturing method of the TFT substrate according to an embodiment of the present application, and FIG. 7 is a schematic diagram of effects of the conductive layer after the etching in the manufacturing method of the TFT substrate of FIG. 6 is completed. It should be noted that since the standard electrode potential of the first metal layer 51 is lower than the standard electrode potential of the second metal layer 52, Galvanic corrosion effect can be formed between the first metal layer 51 and the second metal layer 52 during the etching process of the conductive layer 50, and the first metal layer 51 acts as an anode, and the second metal layer 52 acts as a cathode. A contact area between the anode (the first metal layer 51) and the etching solution is defined as a, and it can be understood that a is a total area of a side surface 515 of the first metal layer 51, and the greater the thickness of the first metal layer 51, the greater the a. A contact area between the cathode (the second metal layer 52) and the etching solution is defined as b, and it can be understood that b is the total area of a side surface 525 of the second metal layer 52.

As shown in FIG. 6, when the thickness of the first metal layer 51 is 50 Å to 150 Å, since the thickness of the first metal layer 51 is small, the contact area a between the anode (the first metal layer 51) and the etching solution is small. Therefore, the ratio b/a between the contact area b of the cathode (the second metal layer 52) and the etching solution and the contact area a of the anode (the first metal layer 51) and the etching solution is larger, and when b/a is larger, a corrosion rate of the anode (the first metal layer 51) is faster, so a gap 80 will be formed between the first metal layer 51 and the second metal layer 52.

As can be seen from FIG. 6, since an amount of etching solution filled in the gap 80 is small, so the etching ability is weak, and a longitudinal etching rate of the portion corresponding to the gap 80 on the second metal layer 52 is thus relatively small. The amount of etchant on the layer 52 corresponding to the portion 520 on a periphery of the gap 80 is relatively large. Therefore, the longitudinal etching rate of the portion 520 on the second metal layer 52 corresponding to the periphery of the gap 80 is relatively large, which finally makes an edge area of the second metal layer 52 shows a trend of gradually decreasing thickness, thus forming a smaller taper angle α1 (as shown in FIG. 7).

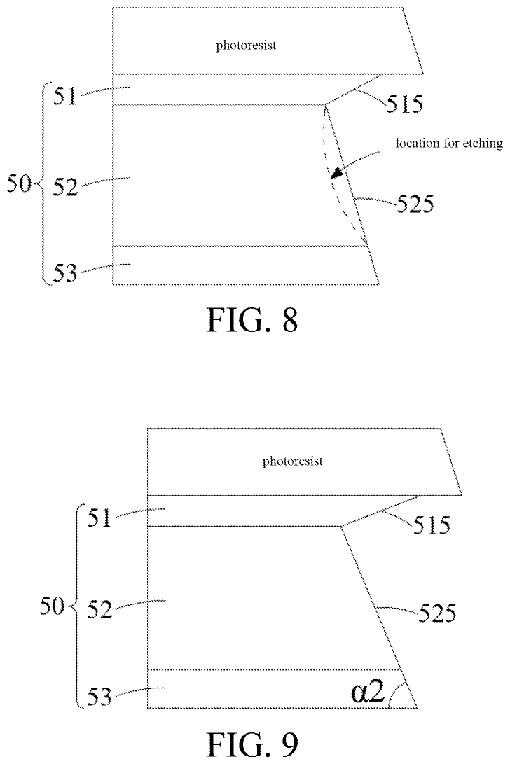

Please refer to FIG. 8 and FIG. 9, FIG. 8 is a schematic diagram of the process of etching the conductive layer in the manufacturing method of the TFT substrate according to another embodiment of the present application, and FIG. 9 is a schematic diagram of showing effects after etching of the conductive layer in the manufacturing method of the TFT substrate of FIG. 8. As shown in FIG. 8, when the thickness of the first metal layer 51 is 300 Å, since the thickness of the first metal layer 51 is large, that is, the contact area a between the anode (the first metal layer 51) and the etching solution is large, so that the ratio b/a between the contact area b of the cathode (the second metal layer 52) and the etching solution and the contact area a of the anode (the first metal layer 51) and the etching solution is smaller. When b/a is smaller, the slower of the corrosion rate the anode (the first metal layer 51) is. It is difficult to form a gap between the first metal layer 51 and the second metal layer 52. The etching solution mainly erodes the side surface 525 of the second metal layer 52 from a lateral direction. The lateral etching rates of the second metal layer 52 in the vertical direction (the direction from the first metal layer 51 to the third metal layer 53) are relatively close, so a larger taper angle α2 is finally formed (as shown in FIG. 9).

After the step S200, the manufacturing method of the TFT substrate according to the embodiment of the present application may further comprise:

Step S300, please refer to FIG. 5, a passivation layer 70 is disposed on a side of the source and drain layer away from the substrate 10.

For example, the material of the passivation layer 70 may comprise one or a plurality of silicon nitride (SiNx), silicon oxide (SiOx), and silicon oxynitride (SiOxNy).

Referring to FIG. 5, an angle α3 (i.e. the taper angle) between a side of the source electrode 61 and a plane where the substrate 10 is located by the manufacturing method of the TFT substrate according to the embodiment of the present application is 50° to 70°, such as 50°, 51°, 52°, 53°, 54°, 55°, 56°, 57°, 58°, 59°, 60°, 61°, 62°, 63°, 64°, 65°, 66°, 67°, 68°, 69°, 70°, etc. An angle α4 (that is, the Taper angle) between a side of the drain electrode 62 and the plane where the substrate 10 is located is 50° to 70°, such as 50°, 51°, 52°, 53°, 54°, 55°, 56°, 57°, 58°, 59°, 60°, 61°, 62°, 63°, 64°, 65°, 66°, 67°, 68°, 69°, 70°, etc. For example, α3 is equal to α4. It can be seen that, compared with the source electrode and the drain electrode with the taper angle of 90° obtained by the existing TFT substrate manufacturing method, the embodiment of the present application significantly reduces the taper angle of the source electrode 61 and the drain electrode 62, that is, the sides of the source electrode 61 and the drain electrode 62 have a certain slope, so that the passivation layer 70 can be better attached to the source electrode 61 and the drain electrode 62, and it is not easy to get from the source electrode 61 and the drain electrode 62. Therefore, the source electrode 61 and the drain electrode 62 can be effectively protected.

To sum up, in the manufacturing method of the TFT substrate provided by an embodiment of the present application, the standard electrode potential of the first metal layer 51 is set to be lower than the standard electrode potential of the second metal layer 52. Therefore, during the etching process of the conductive layer 50, a galvanic corrosion effect can be formed between the first metal layer 51 and the second metal layer 52, and the first metal layer 51 acts as an anode, and the second metal layer 52 acts as a cathode. Compared with the technical solution of setting the thickness of the first metal layer 51 to 300Å in the related art, since in this embodiment of the present application, a thickness of the first metal layer 51 is 50Å to 150 Å, so the thickness of the first metal layer 51 is greatly reduced, thereby reducing a contact area between the first metal layer 51 and the etching solution and increasing the b/a ratio between the contact area b of the cathode and the etching solution and the contact area a of the anode and the etching solution. It is known that when b/a increases, the corrosion rate of the anode is increased, so a larger gap will be formed between the first metal layer 51 and the second metal layer 52, which is beneficial to increase the corroded area of the edge of the second metal layer 52 facing the first metal layer 51, so that it is beneficial to reduce the taper angle of the source electrode and the drain electrode. When the taper angle of the source electrode 61 and the drain electrode 62 obtained by etching is small, the passivation layer 70 can be better attached to the source electrode 61 and the drain electrode 62 and will not easily fall off from the source electrode 61 and the drain electrode 62, so that the source electrode 61 and the drain electrode 62 can be effectively protected.

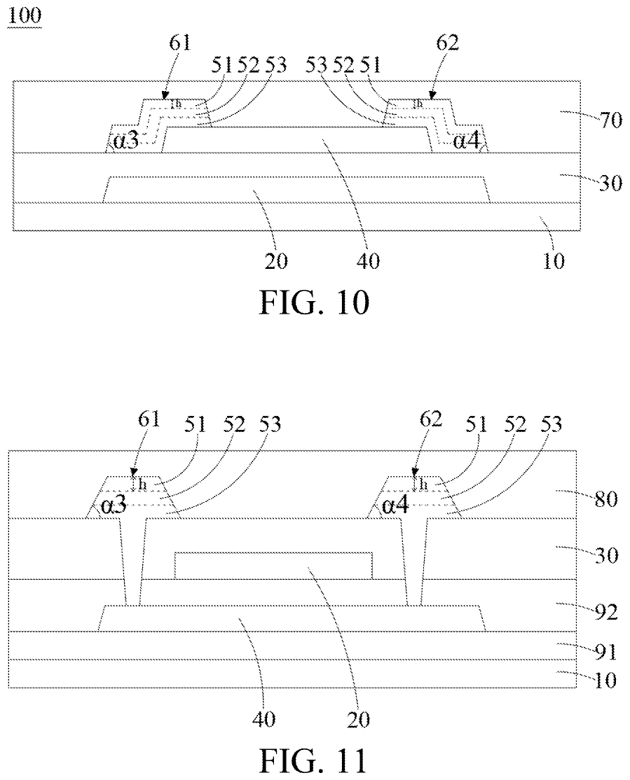

Please refer to FIGS. 10-11, FIG. 10 is a schematic diagram of a first structure of a TFT substrate provided by an embodiment of the present application, and FIG. 11 is a schematic diagram of a second structure of a TFT substrate provided by an embodiment of the present application. The embodiment of the present application further provides a TFT substrate 100, which can be manufactured by using the above-mentioned manufacturing method of the TFT substrate. The TFT substrate 100 may comprise a substrate 10, a gate electrode 20, an active layer 40, a source and drain layer, and a passivation layer 70. Herein the gate electrode 20 and the active layer 40 are both disposed between the substrate 10 and the source and drain layer. Meanwhile, the passivation layer 70 covers a side of the source and drain layer away from the substrate 10, and the source and drain layer comprises a source electrode 61 and a drain electrodes 62 arranged at intervals.

Please refer to FIG. 4, the source electrode 61 and the drain electrode 62 are both obtained by etching the conductive layer 50, and the conductive layer 50 comprises a first metal layer 51 and a second metal layer 52 arranged in a stack, and the first metal layer 51 is arranged on a side of the second metal layer 52 away from the substrate 10. The standard electrode potential of the first metal layer 51 is lower than the standard electrode of the second metal layer 52, and the thickness of the first metal layer 51 is 50Å to 150 Å.

Referring to FIG. 10, the TFT in the TFT substrate 100 may be a bottom-gate TFT. In this case, the TFT substrate 100 may further comprise a gate insulating layer 30, and the substrate 10, the gate electrode 20, the gate insulating layer 30, and the active layer 40, the source and drain layer, and the passivation layer 70 are stacked in sequence.

Herein, the gate insulating layer 30 covers the gate 20, the active layer 40 and the gate 20 are arranged correspondingly, the source 61 and the drain 62 are both in contact with the active layer 40, and the passivation layer 70 covers the source and drain layer and the active layer 40.

Referring to FIG. 11, the TFT in the TFT substrate 100 may also be a top-gate TFT. In this case, the TFT substrate 100 may further comprise a buffer layer 91, a gate insulating layer 92, and an interlayer insulating layer 30. The substrate 10, the buffer layer 91, the active layer 40, the gate insulating layer 92, the gate electrode 20, the interlayer insulating layer 30, the source and drain layer, and the passivation layer 70 are stacked in sequence.

Herein, the gate insulating layer 92 covers the active layer 40, the interlayer insulating layer 30 covers the gate 20, the active layer 40 and the gate 20 are arranged correspondingly, and the gate insulating layer 92 and the interlayer insulating layer 30 are provided with a contact hole of the source electrode 61 and a contact hole of the drain electrode 62. The source electrode 61 is in contact with the active layer 40 through the contact hole of the source electrode 61, the drain electrode 62 is in contact with the active layer 40 through the contact hole of the drain electrode 62, and the passivation layer 70 covers the source and drain layer.

For example, a material of the first metal layer 51 may be a molybdenum-titanium alloy, molybdenum or a molybdenum-niobium alloy, a material of the second metal layer 52 may be copper, and a thickness of the second metal layer 52 may be 2000 Å to 8000 Å.

Referring to FIG. 4, the conductive layer 50 may further comprise a third metal layer 53 and the third metal layer 53 is disposed on a side of the second metal layer 52 away from the first metal layer 51.

For example, a material of the third metal layer 53 may be a molybdenum-titanium alloy, molybdenum or a molybdenum-niobium alloy, and a thickness of the third metal layer 53 may be 100 Å to 500Å.

For example, the angle α3 (i.e. the taper angle) between a side of the source electrode 61 and the plane where the substrate 10 is located is 50° to 70°, and the angle α4 (i.e. the taper angle) between a side of the drain 62 and the plane where the substrate 10 is located is 50° to 70°.

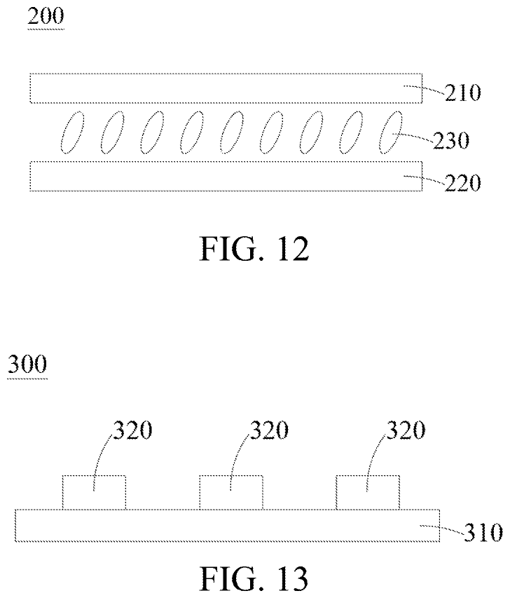

Please refer to FIG. 12, which is a schematic structural diagram of a liquid crystal display panel provided by an embodiment of the present application. Embodiments of the present application further provide a liquid crystal display panel 200, comprising a first substrate 210 and a second substrate 220 disposed opposite to each other, and a liquid crystal layer 230 sandwiched between the first substrate 210 and the second substrate 220. Herein, the second substrate 20 may be the TFT substrate 100 in any of the above-mentioned embodiments or the TFT substrate 100 produced by the manufacturing method of the TFT substrate in any of the above-mentioned embodiments.

For example, the first substrate 210 may be a color filter (CF) substrate.

Please refer to FIG. 13, which is a schematic structural diagram of an OLED display panel provided by an embodiment of the present application. Embodiments of the present application further provide an OLED display panel 300, which comprising a driving substrate 310 and an OLED device 320. The OLED device 320 is disposed on the driving substrate 310, and the OLED device 320 is electrically connected to the driving substrate 310. The driving substrate 310 may be the TFT substrate 100 in any of the foregoing embodiments or the TFT substrate 100 manufactured by the manufacturing method of the TFT substrate in any of the foregoing embodiments.

For example, the OLED device 320 may comprise an anode (Anode), a hole injection layer (HIL, Hole Injection Layer), a hole transport layer (HTL, Hole Transport Layer), an emission layer (EML, Emission layer), an electron Transport Layer (ETL, Electron Transport Layer) and a cathode (Cathode) that are stacked in sequence.

The TFT substrate and the manufacturing method thereof, the liquid crystal display panel and the OLED display panel provided in the embodiments of the present application are described in detail above. Specific examples are used in this article to illustrate the principles and implementations of the present application. The description of the above embodiments is only used to help understand the present application The method of application and its core idea; meanwhile, for those skilled in the art, according to the idea of this application, there will be changes in the specific implementation and the scope of application. In summary, the content of this specification should not be understood as Restrictions on this application.

What is claimed is:

1. A TFT substrate, comprising a substrate, a gate electrode, an active layer, a source and drain layer, and a passivation layer, wherein:
the gate electrode and the active layer are both arranged between the substrate and the source and drain layer, the passivation layer covers a side of the source and drain layer away from the substrate, and the source and drain layer comprises a source electrode and a drain electrode arranged at intervals; and
the source electrode and the drain electrode are both obtained from etching a conductive layer, the conductive layer comprises a first metal layer and a second metal layer that are arranged in a stack, the first metal layer is arranged on a side of the second metal layer away from the substrate, a standard electrode potential of the first metal layer is lower than a standard electrode potential of the second metal layer, and a thickness of the first metal layer is 50Å to 150 Å.

2. The TFT substrate according to claim 1, wherein a material of the first metal layer is a molybdenum-titanium alloy, molybdenum or a molybdenum-niobium alloy, a material of the second metal layer is copper, and a thickness the second metal layer is 2000Å to 8000 Å.

3. The TFT substrate according to claim 1, wherein the conductive layer further comprises a third metal layer, and the third metal layer is disposed on a side of the second metal layer away from the first metal layer; and
a material of the third metal layer is a molybdenum-titanium alloy, molybdenum or a molybdenum-niobium alloy, and a thickness of the third metal layer is 100Å to 500Å.

4. The TFT substrate according to claim 1, wherein an angle between a side of the source electrode and a plane where the substrate is located is 50° to 70°, and an angle between a side of the drain electrode and the plane where the substrate is located is 50° to 70°.

5. The TFT substrate according to claim 1, wherein the TFT substrate further comprises a gate insulating layer, the substrate, the gate electrode, the gate insulating layer, the active layer, the source and drain layer, and the passivation layer that are stacked in sequence; and
wherein the gate insulating layer covers the gate, the active layer and the gate are arranged correspondingly, the source electrode and the drain electrode are both in contact with the active layer, and the passivation layer covers the source and drain layer and the active layer.

6. The TFT substrate according to claim 1, wherein the TFT substrate further comprises a gate insulating layer and an interlayer insulating layer, the substrate, the active layer, the gate insulating layer, the gate electrode, the interlayer insulating layer, the source and drain layers, and the passivation layer that are stacked in sequence; and
wherein the gate insulating layer covers the active layer, and the interlayer insulating layer covers the a gate, the active layer and the gate are arranged correspondingly, and a source contact hole and a drain contact hole are formed in the gate insulating layer and the interlayer insulating layer, and the source electrode is in contact with the active layer through the source contact hole, the drain electrode is in contact with the active layer through the drain contact hole, and the passivation layer covers the source and drain layer.

7. A manufacturing method of a TFT substrate, comprising:
providing a substrate is provided, and arranging a gate electrode, an active layer and a conductive layer on the substrate, wherein:
the gate electrode and the active layer are both arranged between the substrate and the source and drain layer, the passivation layer covers a side of the source and drain layer away from the substrate; and
the conductive layer comprises a first metal layer and a second metal layer that are arranged in a stack, the first metal layer is arranged on a side of the second metal layer away from the substrate, a standard electrode potential of the first metal layer is lower than a standard electrode potential of the second metal layer, and a thickness of the first metal layer is 50Å to 150 Å.
etching the conductive layer, and obtaining the source and drain layer, wherein the source and drain layer comprises a source electrode and a drain electrode arranged at intervals; and
arranging a passivation layer on a side of the source and drain layer away from the substrate.

8. The manufacturing method of the TFT substrate according to claim 7, wherein a material of the first metal layer is a molybdenum-titanium alloy, molybdenum or a molybdenum-niobium alloy, a material of the second metal layer is copper, and a thickness the second metal layer is 2000Å to 8000 Å.

9. The manufacturing method of the TFT substrate according to claim 7, wherein the conductive layer further comprises a third metal layer, and the third metal layer is disposed on a side of the second metal layer away from the first metal layer; and
a material of the third metal layer is a molybdenum-titanium alloy, molybdenum or a molybdenum-niobium alloy, and a thickness of the third metal layer is 100Å to 500 Å.

10. The manufacturing method of the TFT substrate according to claim 7, wherein an angle between a side of the source electrode and a plane where the substrate is located is 50° to 70°, and an angle between a side of the drain electrode and the plane where the substrate is located is 50° to 70°.

11. A liquid crystal display panel, comprising:
a first substrate;
a second substrate disposed opposite to the first substrate, wherein the second substrate is the TFT substrate according to claim 1; and
a liquid crystal layer sandwiched between the first substrate and the second substrate.

12. The liquid crystal display panel according to claim 11, wherein a material of the first metal layer is a molybdenum-titanium alloy, molybdenum or a molybdenum-niobium alloy, a material of the second metal layer is copper, and a thickness the second metal layer is 2000Å to 8000 Å.

13. The liquid crystal display panel according to claim 11, wherein the conductive layer further comprises a third metal layer, and the third metal layer is disposed on a side of the second metal layer away from the first metal layer; and
a material of the third metal layer is a molybdenum-titanium alloy, molybdenum or a molybdenum-niobium alloy, and a thickness of the third metal layer is 100Å to 500 Å.

14. The liquid crystal display panel according to claim 11, wherein an angle between a side of the source electrode and a plane where the substrate is located is 50° to 70°, and an angle between a side of the drain electrode and the plane where the substrate is located is 50° to 70°.

15. The liquid crystal display panel according to claim 11, wherein the TFT substrate further comprises a gate insulating layer, the substrate, the gate electrode, the gate insulating layer, the active layer, the source and drain layer, and the passivation layer that are stacked in sequence; and
wherein the gate insulating layer covers the gate, the active layer and the gate are arranged correspondingly, the source electrode and the drain electrode are both in contact with the active layer, and the passivation layer covers the source and drain layer and the active layer.

16. An OLED display panel, comprising:
a driving substrate, wherein the driving substrate is the TFT substrate according to claim 1; and
an OLED device disposed on the driving substrate, wherein the OLED device is electrically connected to the driving substrate.

17. The OLED display panel according to claim 16, wherein a material of the first metal layer is a molybdenum-titanium alloy, molybdenum or a molybdenum-niobium alloy, a material of the second metal layer is copper, and a thickness the second metal layer is 2000Å to 8000Å.

18. The OLED display panel according to claim 16, wherein the conductive layer further comprises a third metal layer, and the third metal layer is disposed on a side of the second metal layer away from the first metal layer; and
a material of the third metal layer is a molybdenum-titanium alloy, molybdenum or a molybdenum-niobium alloy, and a thickness of the third metal layer is 100Å to 500Å.

19. The OLED display panel according to claim 16, wherein an angle between a side of the source electrode and a plane where the substrate is located is 50° to 70°, and an angle between a side of the drain electrode and the plane where the substrate is located is 50° to 70°.

20. The OLED display panel according to claim 16, wherein the TFT substrate further comprises a gate insulating layer, the substrate, the gate electrode, the gate insulating layer, the active layer, the source and drain layer, and the passivation layer that are stacked in sequence; and
wherein the gate insulating layer covers the gate, the active layer and the gate are arranged correspondingly, the source electrode and the drain electrode are both in contact with the active layer, and the passivation layer covers the source and drain layer and the active layer.
